(19) United States
(12) Patent Application Publication
(10) Pub. No.: US 2002/0011626 A1
(43) Pub. Date: Jan. 31, 2002

(54) RESURF LDMOS integrated structure

(75) Inventors: Giuseppe Croce, Concorezzo (IT); Alessandro Moscatelli, Casnate con Bernate (IT); Alessandra Merlini, Nova Milanese (IT); Paola Galbiati, Monza (IT)

Correspondence Address: CHRISTOPHER F. REGAN, Allen, Dyer, Doppelt, Milbrath & Gilchrist, P.A., P.O. Box 3791, Orlando, FL, 32802-3791, US

(73) Assignee: STMicroelectronics S.r.l., Agrate Brianza (IT)

(21) Appl. No.: 09/839,596

(22) Filed: Apr. 20, 2001

(30) Foreign Application Priority Data
Apr. 21, 2000 (EP) 00830308.3

(51) Int. Cl. H01L 29/76

(52) U.S. Cl. 257/335

(57) ABSTRACT

A reduced surface field (RESURF) lateral diffused metal oxide semiconductor (LDMOS) integrated circuit includes a first region having a first conductivity type defined in a semiconductor substrate having a second conductivity type, a body region having the second conductivity type in the first region, and a source region having the first conductivity type formed in the body region. More specifically, the body region may be within a surface portion of the first region that is more heavily doped than the remainder of the of the first region.

### FIELD OF THE INVENTION

The present invention relates to the field of electronic circuits, and, more particularly, to reduced surface field (RESURF) integrated circuits.

### BACKGROUND OF THE INVENTION

RESURF integrated circuits typically include power devices capable of withstanding relatively high voltages, typically n-channel lateral diffused metal oxide semiconductor (LDMOS) and/or lateral p-channel MOS transistors, which may respectively function with their sources or drains disconnected from ground. The ability to withstand a relatively high voltage of field effect complementary MOS (CMOS) lateral transistors such as, for example, n-channel LDMOS and p-channel MOS transistors, may be enhanced through the so-called RESURF effect. The RESURF effect is achieved by using a relatively thin epitaxial layer and by accurately controlling the diffusion implants to allow integration of lateral CMOS transistors capable of withstanding relatively high voltages.

RESURF LDMOS structures are of particular interest because they offer a good compromise between specific resistance and breakdown voltage, reducing power dissipation as well as the thickness of silicon die. One important objective of designing an LDMOS RESURF structure is ensuring that the drain well region is completely depleted before critical electric fields develop corresponding to the gate oxide.

To better understand the principle behind RESURF LDMOS structures, reference is now made to FIGS. 1a and 1b. These figures illustrate two possible conditions of operation at different drain-source voltages (VDS). The illustrated LDMOS structure includes a p-substrate 11, a drain well region 12 having an opposite type of conductivity from the p-substrate, and a body region 13. The figures also show the junctions between the p-substrate 11 and drain well region 12 and between the drain well region and body region 13.

A typical shape of the depletion regions of the two above noted junctions is illustrated in FIG. 1a where the source 14, the body region 13, and the gate are connected to a reference potential GND and a certain VDS voltage (e.g., VDS=20 V) is applied to the drain. Under these operating conditions, the junctions are inversely biased because of the applied VDS voltage, and the respective depletion regions extend into the drain well region 12 down to a certain depth. By further incrementing the VDS voltage, as shown in FIG. 1b (e.g., VDS=25 V), the depletion regions of the junctions between the substrate 11 and the drain well region 12 and between the drain well region and the body region 13 merge. This completely depletes the drain well region 12, thus producing the desired RESURF condition.

Under certain conditions of operation in which relatively high drain gate and source voltages are applied while keeping the substrate at ground GND (e.g., a high side driver), the total depletion of the drain well region 12 may cause a punch-through (PT) phenomena between the body region 13 and the substrate 11. For this reason, RESURF LDMOS structures are commonly used as low side drivers, i.e., operated with the source 14 and the substrate at ground potential. Yet, there is a need for a RESURF LDMOS structure capable of functioning as a high side driver without the drawbacks and limitations of known devices.

### SUMMARY OF THE INVENTION

It is an object of the present invention to provide a RESURF LDMOS structure that may be used at relatively high voltages with a reduction in punch-through problems.

This and other objects, features, and advantages are provided by an anti punch-through (PT) region between the body and the drain well region which has the same conductivity type as the drain well region but is more heavily doped. More precisely, an integrated RESURF LDMOS structure according to the invention includes a first region (drain well region) of a first conductivity type in a semiconductor substrate. A body region of a second conductivity type is in a surface portion of the first region. The surface portion of the first region is preferably more heavily doped than the remainder of the first region. A source region of the first conductivity type is formed in the body region. For example, an n-channel RESURF LDMOS structure according to the invention may include an n-type epitaxial layer having a thickness of about 3 μm doped with phosphorous at a concentration of about 6*10¹⁵ atoms cm⁻³, a body region doped with boron at a concentration of about 10¹⁸ atoms cm⁻³, and a surface portion of the first region having a dopant concentration of about 5×10¹⁶ to 10¹⁷ atoms cm⁻³.

### BRIEF DESCRIPTION OF THE DRAWINGS

The various aspects and advantages of the invention will become more apparent through the following detailed description and by referring to the details shown in the attached drawings, wherein:

FIGS. 1a and 1b are cross-sectional views illustrating the depletion regions in a traditional RESURF LDMOS structure according to the prior art at two different drain-source voltages (VDS);

FIG. 2 is a cross-sectional view illustrating a traditional LDMOS structure according to the prior art and a cross-sectional view illustrating an LDMOS structure of the invention;

FIG. 3a is a cross-sectional diagram illustrating potential lines occurring during operation of an LDMOS transistor as a low side driver according to the invention; and

FIG. 3b is a cross-sectional diagram illustrating charge concentration distribution during operation of an LDMOS transistor as a high side driver according to the invention.

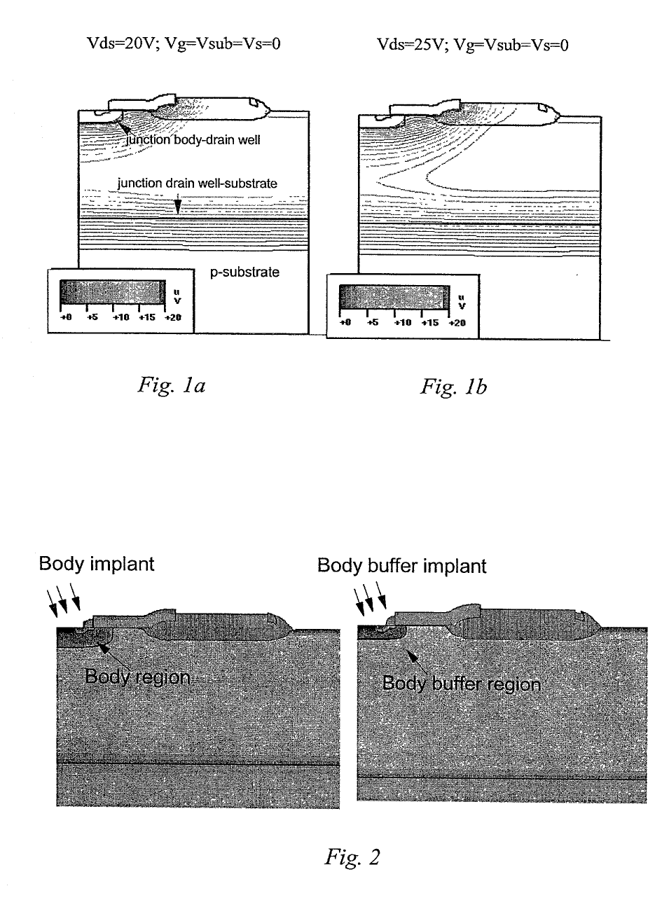

### DETAILED DESCRIPTION OF THE PREFERRED EMBODIMENTS

The present invention provides a relatively simple and effective solution to punch-through (PT) problems that normally limit the performance of known RESURF LDMOS structures when functioning as high side drivers. This is done without introducing substantial changes in the known RESURF LDMOS structure. The invention is directed to a RESURF LDMOS structure that includes a superficial or surface portion (or body buffer region) 15 of the drain well region 12 which surrounds the body region 13. The body buffer region 15 is preferably more heavily doped than the remaining portion of the drain well region 12, as shown in FIG. 2. In the drawings, like numbers are used throughout to refer to similar elements for clarity of illustration.

By making the body buffer region 15 more heavily doped than the remainder of the drain well region 12, a significant enhancement of the RESURF LDMOS structure performance is achieved, especially when functioning as a high side driver at relatively high VDS voltages. As opposed to what occurs in the remainder of the drain well region 12, the body buffer region 15 is not completely depleted during operation. Thus, punch-through problems that restrict the conditions under which present LDMOS structures may safely be used are reduced.

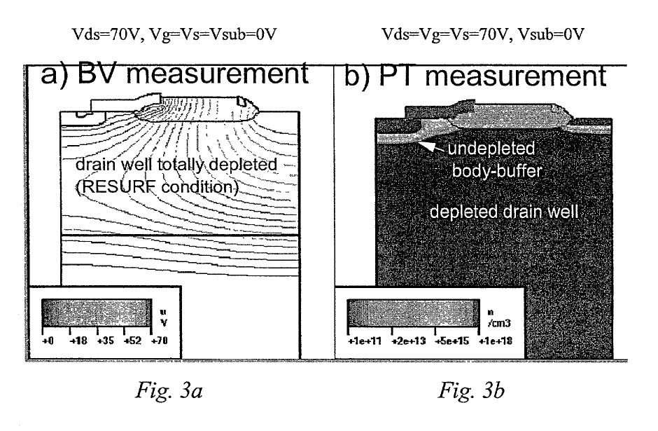

The principles upon which the RESURF LDMOS structure of the invention are based will be better understood with reference to FIGS. 3a and 3b. As shown in FIG. 3b, even if relatively high voltages are applied to the drain and source (typical of a high-side application), the drain well region 12 will be completely depleted of its charge before the body buffer region 15 is depleted. This is due to the heavier doping of the body buffer region 15. This substantially prevents the occurrence of PT phenomena at relatively low voltages, which in turn enhances the performance of the structure of the invention under critical conditions of use.

In practice, the presence of the body buffer region 15 increases the level of voltage that must be reached before punch-through results. On the other hand, it may lower the breakdown voltage (BV). As such, the thickness and the doping level of the body buffer region 15 should be established to achieve the appropriate compromise between increasing the voltage level at which the punch-through may occur and ensuring a sufficiently high breakdown voltage. These parameters of the body buffer region 15 may be accurately established at the design stage so that only negligible or tolerable reductions of the breakdown voltage are introduced.

The following tables provide exemplary fabrication process parameters according to the invention. Table 1 is for an integrated n-channel RESURF LDMOS of the invention in a p-type epitaxial layer and Table 2 is for a p-channel RESURF LDMOS structure in an n-type epitaxial layer.

TABLE 1

| | | Thickness | Doping [Atoms |
|---|---|---|---|
| Region | Dopant | [μm] | cm⁻³] |
| p-body (conductivity | boron | 0.25-0.75 | 5 × 10¹⁷-5 × 10¹⁸ |
| “P”) | | | |
| body-buffer | phosphorous | 0.15-0.45 | 5 × 10¹⁶-5 × 10¹⁷ |
| (conductivity “N”) | | | |
| drain well region | phosphorous | 1.5-4.5 | 2.5 × 10¹⁵-2.5 × 10¹⁶ |
| (conductivity “N”) | | | |

TABLE 2

| | | Thickness | Doping [Atoms |
|---|---|---|---|
| region | Dopant | [μm] | cm⁻³] |
| n-body (conductivity | phosphorous | 0.25-0.75 | 5 × 10¹⁷-5 × 10¹⁸ |
| “N”) | | | |
| body-buffer | boron | 0.15-0.45 | 5 × 10¹⁶-5 × 10¹⁷ |
| (conductivity “P”) | | | |
| drain well region | boron | 1.5-4.5 | 2.5 × 10¹⁵-2.5 × 10¹⁶ |
| (conductivity “P”) | | | |

FIG. 3a shows a possible distribution of the potential lines in the structure of the invention operating as a low side driver, i.e., with the source 14 and the substrate 11 connected to ground and a positive voltage applied to the drain. The body buffer region 15 is preferably designed to become completely depleted (due to the inverse biasing of the junction between the body and the drain well region 12) before breakdown conditions are reached. Hence, when the drain voltage assumes values close to those of the expected breakdown voltage, the depletion regions of the inversely biased junctions extend into the body buffer region 15 and into the drain well region 12, as shown in FIG. 3a, thus resulting in the RESURF condition.

That which is claimed is:

1. A RESURF LDMOS integrated structure realized in a first region (DRAIN_WELL) of a first type of conductivity defined in a semiconductor substrate (P-SUBSTRATE) of opposite type of conductivity and comprising a source region of said first type of conductivity formed in a body region of said opposite type of conductivity, characterized in that
said body region is contained within a superficial portion (BODY_BUFFER_REGION) of said first region (DRAIN_WELL) more heavily doped than the rest of the region.

2. The integrated structure of claim 1, wherein said first region (DRAIN_WELL) has a depth comprised between 1.5 and 4.5 micrometers and doping comprised between 2.5×10¹⁵ and 2.5×10¹⁶ atoms cm⁻³, said superficial portion (BODY_BUFFER_REGION) is comprised between 0.15 and 0.45 micrometers deep and has a doping comprised between 5×10¹⁶ and 5×10¹⁷ atoms cm⁻³ and the depth of said body region is comprised between 0.25 and 0.75 micrometers and has a doping comprised between 5×10¹⁷ and 5×10¹⁸ atoms cm⁻³.

3. The integrated structure according to claims 1 or 2, wherein said first region (DRAIN_WELL) and said superficial portion thereof (BODY_BUFFER_REGION) are doped with phosphorous while said body region is doped with boron.

4. The integrated structure according to one of the claims 1 or 2, wherein said first region (DRAIN_WELL) and said superficial portion thereof (BODY_BUFFER_REGION) are doped with boron while said body region is doped with phosphorus.
